(19) United States
(12) Patent Application Publication
(10) Pub. No.: US 2026/0029496 A1
(43) Pub. Date: Jan. 29, 2026

(54) MAGNETIC RESONANCE IMAGING APPARATUS AND SHIM TRAY

(71) Applicant: CANON MEDICAL SYSTEMS CORPORATION, Otawara-shi (JP)

(72) Inventors: Hiroki HATTORI, Nasushiobara (JP); Ayumi KATSUNUMA, Himeji (JP)

(73) Assignee: CANON MEDICAL SYSTEMS CORPORATION, Otawara-shi (JP)

(21) Appl. No.: 19/250,809

(22) Filed: Jun. 26, 2025

(30) Foreign Application Priority Data
Jul. 26, 2024 (JP) 2024-121180

(51) Int. Cl. G01R 33/3873; G01R 33/3815

(52) U.S. Cl. CPC G01R 33/3873; G01R 33/3815

(57) ABSTRACT

A magnetic resonance imaging apparatus according to an exemplary embodiment includes a magnet gantry including a magnet configured to generate a static magnetic field in a bore and a shim tray including a first shim tray element part and a second shim tray element part, the first shim tray element part including a first shim pocket in which a magnetic shim which is configured to adjust the static magnetic field is stored, and the second shim tray element part including a second shim pocket in which the magnetic shim is stored. Each of the first shim tray element part and the second shim tray element part is inserted into and removed from the magnet gantry along an axial direction of the bore through at least one of openings provided on one end side of the magnet gantry and the other end side of the magnet gantry in the axial direction.

### CROSS-REFERENCE TO RELATED APPLICATIONS

This application is based upon and claims the benefit of priority from Japanese Patent Application No. 2024-121180, filed Jul. 26, 2024, the entire contents of which are incorporated herein by reference.

### FIELD

Embodiments disclosed in this specification and in the accompanying drawings relate to a magnetic resonance imaging apparatus and a shim tray.

### BACKGROUND

Magnetic resonance imaging (MRI) apparatus are demanded to have excellent spatial uniformity (that is, magnetic field uniformity) in the static magnetic field in the imaging region, in order to obtain high-quality magnetic resonance (MR) images. The magnetic field uniformity is affected by, for example, the environment in which the MRI apparatus is installed and the manufacturing error of the static magnetic field magnet. Thus, in installing the MRI apparatus, the static magnetic field is adjusted (that is, shimmed) such that the magnetic field uniformity in the imaging region within the bore of the MRI apparatus satisfies a specified value.

Shimming is performed by, for example, housing magnetic shims made of metal members, such as iron pieces, in shim trays, and then fitting the shim trays into the shim slots arranged in the magnet gantry of the MRI apparatus. In shimming, a series of shimming operations are repeated, including placing the magnetic shims in the shim trays, inserting the shim trays into the magnet gantry, exciting the static magnetic field magnet, measuring the magnetic field uniformity, and demagnetizing the static magnetic field magnet if the magnetic field uniformity is lower than a specified value, and removing the shim trays from the magnet gantry. The demagnetization and excitation of the static magnetic field magnet in the shimming operations consume helium for cooling the static magnetic field magnet, increasing work hours.

### BRIEF DESCRIPTION OF THE DRAWINGS

FIG. 1 is a block diagram illustrating an example of an overall configuration of a magnetic resonance imaging (MRI) apparatus according to an exemplary embodiment;

FIG. 2 is a schematic perspective view of a configuration example of a magnet gantry of the MRI apparatus according to an exemplary embodiment;

FIG. 3 is a schematic perspective view of a configuration example of a shim tray according to a first exemplary embodiment;

FIG. 4 is a cross-sectional view of a portion of a magnet gantry of an MRI apparatus according to the first exemplary embodiment;

FIG. 5 is a cross-sectional view for illustrating an example of insertion and removal directions of the shim tray according to the first exemplary embodiment;

FIGS. 6A and 6B are cross-sectional views for illustrating another example of insertion and removal directions of the shim tray according to the first exemplary embodiment;

FIG. 7 is a flowchart illustrating an example of shimming operations in the MRI apparatus according to the exemplary embodiment;

FIGS. 8A and 8B are cross-sectional views for illustrating an example of a shim tray according to a second exemplary embodiment;

FIGS. 9A and 9B are cross-sectional views for illustrating another example of the shim tray according to the second exemplary embodiment;

FIGS. 10A to 10C are cross-sectional views for illustrating examples of shim trays according to modifications of the second exemplary embodiment; and

FIG. 11 is a cross-sectional view of a portion of a magnet gantry of an MRI apparatus according to a third exemplary embodiment.

### DETAILED DESCRIPTION

A magnetic resonance imaging (MRI) apparatus according to an exemplary embodiment includes a magnet gantry including a magnet configured to generate a static magnetic field in a bore in which a subject is positioned and a shim tray including a first shim tray element part and a second shim tray element part, the first shim tray element part including a first shim pocket in which a magnetic shim which is configured to adjust the static magnetic field is stored, and the second shim tray element part including a second shim pocket in which the magnetic shim is stored. Each of the first shim tray element part and the second shim tray element part is inserted into and removed from the magnet gantry along an axial direction of the bore through at least one of openings provided on one end side of the magnet gantry and the other end side of the magnet gantry in the axial direction.

Various Embodiments will be described hereinafter with reference to the accompanying drawings.

Exemplary embodiments of an MRI apparatus will be described in detail with reference to the accompanying drawings. In each drawing, identical elements are given identical reference numerals and the descriptions thereof will be omitted.

### (Overall Configuration of MRI Apparatus)

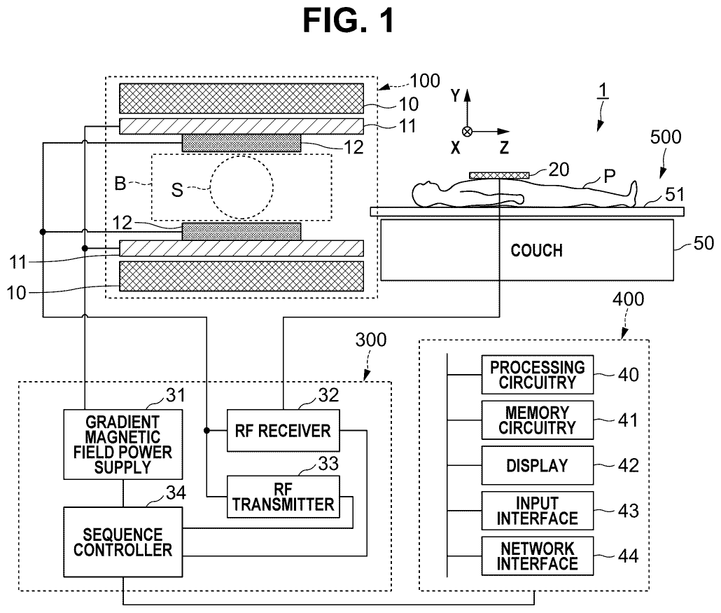

FIG. 1 is a block diagram of an example of an overall configuration of an MRI apparatus 1 according to an exemplary embodiment. The MRI apparatus 1 includes a magnet gantry 100, a control cabinet 300, an image processing device 400 (e.g., a console), and a couch 500. In the magnet gantry 100 and the couch 500, the left-right direction of a subject P positioned on the couch 500 is defined as the X-axis direction, the front-back direction (thickness direction) is defined as the Y-axis direction, and the head-to-foot direction is defined as the Z-axis direction.

The magnet gantry 100 includes a static magnetic field magnet 10, a gradient magnetic field coil 11, and a whole body (WB) coil 12. These components are housed in a cylindrical housing.

The static magnetic field magnet 10 is a superconducting magnet that has a roughly cylindrical shape and generates a static magnetic field within the space inside the cylinder, specifically, the cylindrical bore B, where the subject P (e.g., a patient) is positioned. The static magnetic field magnet 10 incorporates a superconducting coil, which is cooled to a cryogenic temperature by liquid helium. In an excitation mode, the static magnetic field magnet 10 generates a static magnetic field through the application of current supplied from a static magnetic field power supply (not illustrated) to the superconducting coil. Additionally, in a demagnetization mode, the static magnetic field magnet 10 reduces or eliminates the static magnetic field through the application of current supplied from the static magnetic field power supply to the superconducting coil. When the static magnetic field magnet 10 transitions to a persistent current mode, the static magnetic field magnet 10 is disconnected from the static magnetic field power supply and continues to generate a large static magnetic field for a long period of time, such as over a year.

The gradient magnetic field coil 11 has a roughly cylindrical shape and is arranged inside the static magnetic field magnet 10. The gradient magnetic field coil 11 generates a gradient magnetic field in accordance with power (current) supplied from a gradient magnetic field power supply 31. The gradient magnetic field is applied to the subject P.

In order to reduce the eddy current that would occur with the generation of this gradient magnetic field, an actively shielded gradient coil (ASGC) may be used as the gradient magnetic field coil 11. The ASGC includes main coils for generating gradient magnetic fields in the X-axis, Y-axis, and Z-axis directions, shim trays capable of accommodating a plurality of magnetic shims, and shield coils for suppressing leakage of the magnetic fields.

The WB coil 12, also called a whole body coil, has a roughly cylindrical shape and is disposed inside the gradient magnetic field coil 11 so as to surround the subject P. The WB coil 12 transmits radio frequency (RF) pulses transmitted from an RF transmitter 33, toward the subject P, and receives magnetic resonance (MR) signals emitted from the subject P due to excitation of nuclear spins.

The MRI apparatus 1 may include a local coil 20 in addition to the WB coil 12. The local coil 20 is also called a topical coil, and is disposed adjacent to the body surface of the subject P. Examples of the types of the local coil 20 include head coils, chest coils, abdominal coils, spine coils, and knee coils. The local coil 20 includes reception-specific coils, transmission-specific coils, and transmission and reception coils configured to perform both transmission and reception. The local coil 20 is attachable to and detachable from a couchtop 51 via a cable, for example.

The couch 500 includes a couch body 50 and the couchtop 51. The couch body 50 is capable of moving the couchtop 51 in the vertical and horizontal directions. The couch body 50 moves the subject P positioned on the couchtop 51 to a predetermined height, and then moves the couchtop 51 in the horizontal direction to position the subject P in the bore B.

The control cabinet 300 includes a gradient magnetic field power supply 31, an RF receiver 32, an RF transmitter 33, and a sequence controller 34.

The gradient magnetic field power supply 31 supplies power to the gradient magnetic field coil 11 under the control of a sequence controller 34 to generate gradient magnetic fields along the X axis, Y axis, and Z axis.

The RF transmitter 33 generates RF pulses under the control of the sequence controller 34. The generated RF pulses are transmitted to the WB coil 12 or the local coil 20 and applied to the subject P. The RF receiver 32 detects MR signals received by the WB coil 12 or the local coil 20, subjects the detected MR signals to analog-to-digital (AD) conversion, and outputs the converted signals to the sequence controller 34. The digitized MR signals are called raw data.

The sequence controller 34, under the control of the image processing device 400, drives the gradient magnetic field power supply 31, the RF receiver 32, and the RF transmitter 33 to execute the scan of the subject P. The sequence controller 34 transmits raw data collected through the scan to the image processing device 400.

The sequence controller 34 includes processing circuitry (not illustrated) that includes hardware components, such as a processor that executes predetermined programs, a field programmable gate array (FPGA), and an application specific integrated circuit (ASIC).

The image processing device 400 includes processing circuitry 40, memory circuitry 41, a display 42, and an input interface 43. The image processing device 400 may also include a network interface 44.

The processing circuitry 40 is circuitry including a central processing unit (CPU) or a dedicated or general-purpose processor, for example. The processor implements various functions through software processing by executing various programs stored in the memory circuitry 41 or directly embedded in the processing circuitry 40.

The memory circuitry 41 includes a storage medium including a semiconductor memory element, such as a random access memory (RAM) or a flash memory, and an external storage device, such as a hard disk or an optical disk, for example. The memory circuitry 41 may be a portable medium, such as a universal serial bus (USB) memory or a digital video disk (DVD). The memory circuitry 41 stores various types of information and data, and stores various programs to be executed by the processor of the processing circuitry 40.

The display 42 includes a display device, such as a liquid crystal display or an organic light emitting diode (OLED) display. The display 42 displays various types of information under the control of the processing circuitry 40. The display 42 may be a graphic user interface (GUI) that functions as both a display device and an input device.

The input interface 43 includes an input device and input circuitry. The input device is implemented by a trackball, a switch, a mouse, a keyboard, a touch pad, a touch screen, a non-contact input device using an optical sensor, a voice input device, or the like. When the input device is operated by a user, the input circuitry generates a signal according to the operation and outputs the signal to the processing circuitry 40.

The network interface 44 communicates with various devices connected to the network by wire or wirelessly, and exchanges various types of information and data with the devices.

Using these components, the image processing device 400 controls the entire MRI apparatus 1. Specifically, the processing circuitry 40 receives instructions regarding imaging conditions and various types of other information through operations performed by a user, such as a medical technician, via the input interface 43. The processing circuitry 40 then causes the sequence controller 34 to execute a scan based on the input imaging conditions, and reconstructs an MR image based on the raw data received from the sequence controller 34. The reconstructed MR image is displayed on the display 42 and stored in the memory circuitry 41.

### (Shimming)

In order to obtain images of good quality with the MRI apparatus 1, excellent magnetic field uniformity is demanded in an imaging region S within the bore B. The magnetic field uniformity is affected by, for example, the environment in which the MRI apparatus 1 is installed and the manufacturing error of the static magnetic field magnet 10. Therefore, in installing the MRI apparatus 1, shimming is performed such that the magnetic field uniformity in the imaging region S satisfies a specified value.

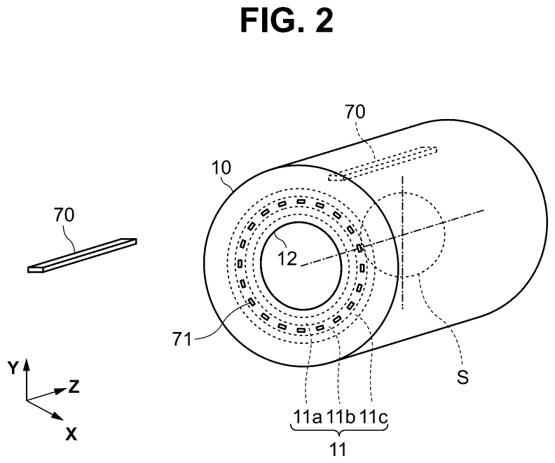

FIG. 2 is a schematic perspective view of a configuration example of the magnet gantry 100 of the MRI apparatus 1 according to the exemplary embodiment.

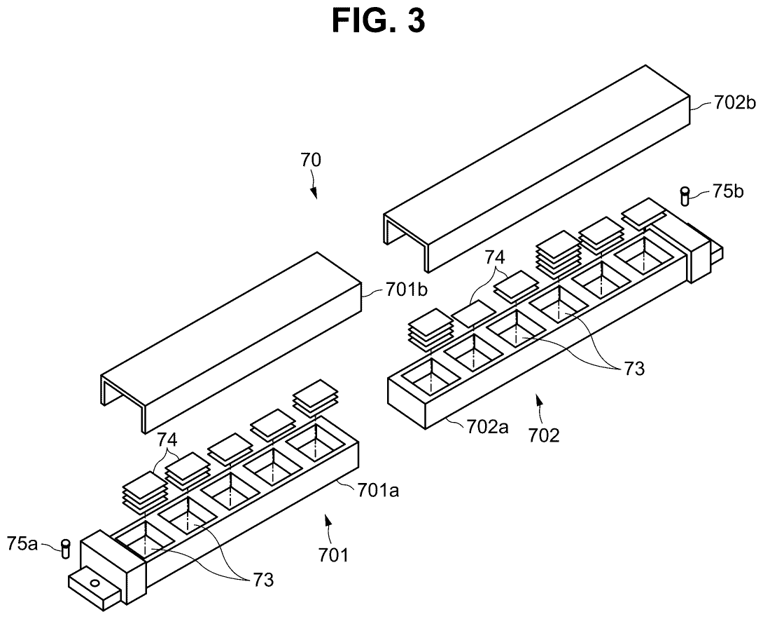

Magnetic shims 74 (see FIG. 3) for adjusting the static magnetic field are housed in columnar shim trays 70 to perform shimming. The shim trays 70 are arranged in the magnet gantry 100 such that its longitudinal direction is along the axial direction of the bore B (i.e., the Z-axis direction). The shim trays 70 are made of, for example, a non-magnetic and non-conductive material, such as glass fiber or resin. Hereinafter, a case where the gradient magnetic field coil 11 is an ASGC, that is, a case where the shim trays 70 are inserted into and removed from the gradient magnetic field coil 11 will be described. However, the shim trays 70 may be inserted into and removed from the magnet gantry 100 independently of the gradient magnetic field coil 11.

The gradient magnetic field coil 11 includes, in order from the center of the bore B, a main coil 11a, a shim tray portion 11b, and a shield coil 11c. The shim tray portion 11b has a roughly cylindrical shape, and includes a plurality of shim slots 71 formed at approximately equal intervals in the circumferential direction of the shim tray portion 11b. The shim slots 71 are through holes formed along the axial direction of the bore B. The plurality of shim trays 70 is inserted into and removed from the plurality of shim slots 71 formed in the gradient magnetic field coil 11, and is arranged parallel to the axial direction of the bore B along the side surface of a cylinder whose central axis is the axis of the bore B. The position, number, shape, and the like of the shim slots 71 formed in the shim tray portion 11b are not limited to those illustrated in FIG. 2.

In conventional shimming, the magnetic field uniformity is measured in a state where the static magnetic field is at a rated magnetic field. On the basis of the measurement results, the arrangement of magnetic shims is calculated to ensure that the magnetic field uniformity in the imaging region S satisfies the specified value. The rated magnetic field refers to the strength of a static magnetic field in a case where a subject is scanned by an MRI apparatus for diagnosis. For safety reasons, the static magnetic field magnet is demagnetized and the shim trays are removed from the magnet gantry, and then the magnetic shims are arranged (e.g., installed or removed) based on the calculation results regarding the arrangement of the magnetic shims. The shim trays are then inserted into the magnet gantry, the static magnetic field is excited, the static magnetic field is set again to the rated magnetic field, and the magnetic field uniformity is measured. This series of shimming operations is repeated until the magnetic field uniformity in the imaging region S satisfies the specified value.

The demagnetization and excitation of the static magnetic field magnet in shimming consume helium, which is a cooling medium for cooling the static magnetic field magnet, and increases the amount of work hours. From the viewpoint of reducing helium consumption and work hours, the shim trays may be inserted and removed in a state where the static magnetic field is at the rated magnetic field. However, this is difficult from a safety perspective in the insertion and removal work because a large magnetic force acts on the entire shim trays. For example, there is a known method with which the shim trays are inserted and removed with a rail-shaped jig attached to the magnet gantry, but attaching the rail-shaped jig requires additional work hours.

Further, if the number of arranged magnetic shims varies depending on the positions of the shim trays, the magnetic force acting on the shim trays also varies depending on the positions of the shim trays. Due to this variation in magnetic force depending on the positions of the shim trays, inserting and removing the shim trays from the magnet gantry while the static magnetic field is at the rated magnetic field can be dangerous, as the magnetic force acting on the shim trays during the insertion and removal process fluctuates.

Thus, in the MRI apparatus 1 according to the exemplary embodiment, each shim tray 70 is divided into a plurality of shim tray element parts (e.g., shim tray element parts 701 and 702 in FIG. 3), and the shim tray element parts are individually inserted into and removed from the magnet gantry 100. Since the shim tray 70 is divided into a plurality of shim tray element parts and the magnetic force acting on each shim tray element part is smaller than the magnetic force acting on the entire shim tray, the insertion and removal work can be safely performed even with the static magnetic field at the rated magnetic field.

### First Exemplary Embodiment

FIG. 3 is a schematic perspective view of a configuration example of a shim tray 70 according to a first exemplary embodiment. The shim tray 70 includes a plurality of shim pockets 73 for housing magnetic shims 74. The shim pockets 73 are recesses formed in the shim tray 70 at predetermined intervals. The magnetic shims 74 are magnetic members such as iron pieces, and are used to adjust the static magnetic field. In shimming, the necessary number of magnetic shims 74 are housed at predetermined positions in the plurality of shim pockets 73 so that the magnetic field uniformity in an imaging region S in a bore B satisfies a specified value.

The shim tray 70 is divided into a plurality of shim tray element parts, based on the positions along the axial direction of the bore B and the magnetic force acting on the shim tray 70 in accordance with the positions. In the first exemplary embodiment, the shim tray 70 is divided into two parts, namely, a first shim tray element part 701 and a second shim tray element part 702. The shim tray element parts 701 and 702 include box portions 701a and 702a and lid portions 701b and 702b, respectively. The lid portions 701b and 702b are lids that cover the box portions 701a and 702a, respectively, after the magnetic shims 74 are housed in the shim pockets 73.

Each of the plurality of shim tray element parts 701 and 702 includes at least one shim pocket 73. In FIG. 3, the first shim tray element part 701 includes five shim pockets 73 in the box portion 701a, and the second shim tray element part 702 includes six shim pockets 73 in the box portion 702a. The positions, numbers, and shapes of the shim pockets 73 of the shim tray element parts 701 and 702, and the positions, numbers, and shapes of the magnetic shims 74 are not limited to those illustrated in FIG. 3. The shim tray 70 is divided into the plurality of shim tray element parts 701 and 702 such that the magnetic force acting on each shim tray element part is smaller than a predetermined value. This predetermined value refers to magnetic force acting on each shim tray element part that is small enough to ensure safety during insertion and removal work. In order to make it easier for all of the shim tray element parts 701 and 702 to satisfy the predetermined value, the shim tray 70 may be divided so that the magnetic force acting on the shim tray element parts 701 and 702 is approximately equal. The positions at which the shim tray 70 is divided vary not only depending on the manufacturing error of the static magnetic field magnet 10 but also depending on the environment in which an MRI apparatus 1 is installed.

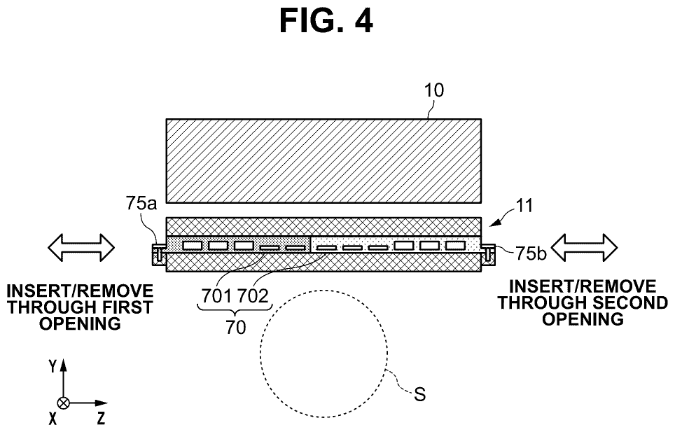

FIG. 4 is a cross-sectional view of a portion of a magnet gantry 100 of the MRI apparatus 1 according to the first exemplary embodiment. The first shim tray element part 701 inserted into the magnet gantry 100 along the axial direction of the bore B is fixed by a first fixing part 75a disposed on one end side of the magnet gantry 100. The second shim tray element part 702 inserted into the magnet gantry 100 along the axial direction of the bore B is fixed by a second fixing part 75b disposed on the other end side of the magnet gantry 100. The shim tray element parts 701 and 702 may be fixed to a gradient magnetic field coil 11 with the fixing parts 75a and 75b via through holes of the shim tray element parts 701 and 702. Each of the shim tray element parts 701 and 702 may be provided with a handle to facilitate insertion into and removal from the magnet gantry 100.

Each of the first shim tray element part 701 and the second shim tray element part 702 is inserted and removed along the axial direction through at least one of openings formed on the one end side and the other end side of the magnet gantry 100 in the axial direction of the bore B. Hereinafter, the opening formed on the one end side of the magnet gantry 100 in the axial direction of the bore B will be referred to as “first opening,” and the opening provided on the other end side of the magnet gantry 100 in the axial direction of the bore B will be referred to as “second opening”.

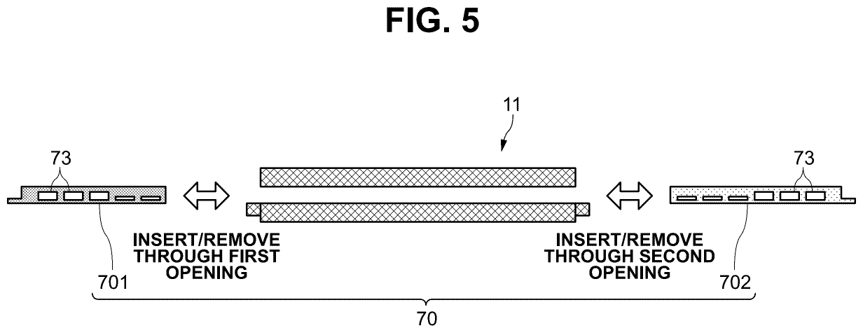

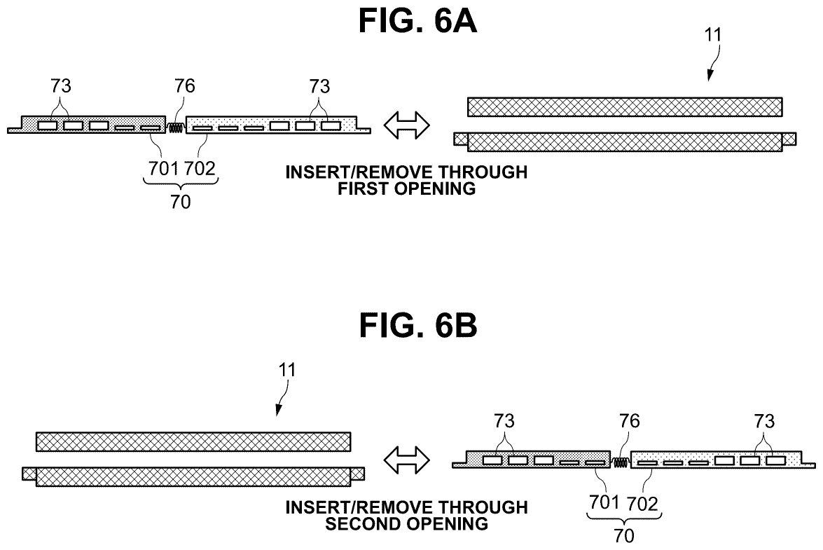

FIGS. 5, 6A, and 6B are cross-sectional views for illustrating the insertion and removal directions of the shim tray 70 according to the first exemplary embodiment. Referring to FIG. 5, the first shim tray element part 701 is inserted into and removed from the magnet gantry 100 along the axial direction of the bore B through the first opening, and the second shim tray element part 702 is inserted into and removed from the magnet gantry 100 along the axial direction of the bore B through the second opening.

In contrast to FIG. 5, referring to FIG. 6A, the first shim tray element part 701 and the second shim tray element part 702 are inserted into and removed from the magnet gantry 100 through the first opening. Additionally, referring to FIG. 6B, the first shim tray element part 701 and the second shim tray element part 702 are inserted into and removed from the magnet gantry 100 through the second opening. Specifically, the opening through which each of the shim tray element parts 701 and 702 is inserted and removed is the same. In these cases, the first shim tray element part 701 and the second shim tray element part 702 can be coupled to each other. A coupling member 76 that couples the first shim tray element part 701 and the second shim tray element part 702 will be described in detail below.

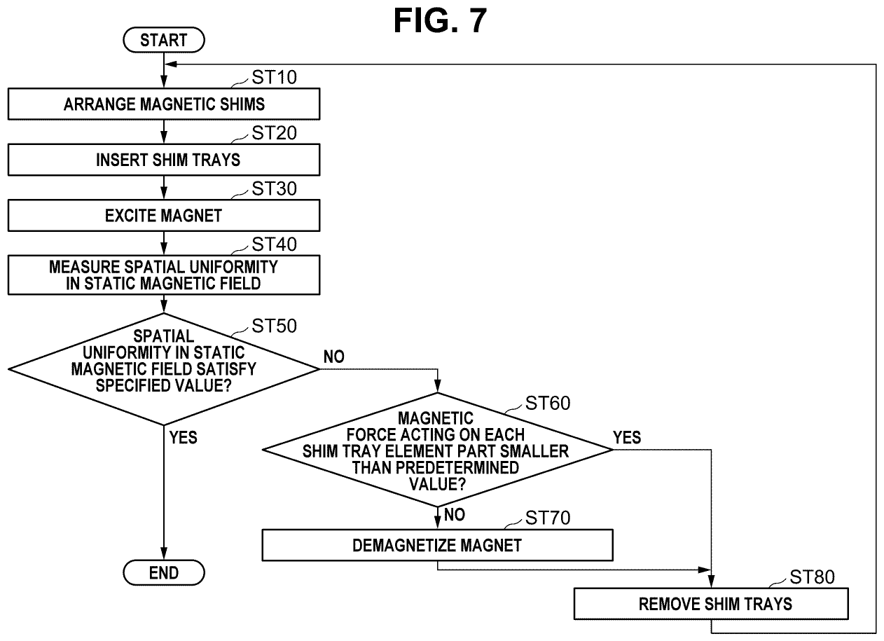

An example of shimming operations in the MRI apparatus 1 according to the present exemplary embodiment will be described with reference to the flowchart in FIG. 7.

In step ST10, the magnetic shims 74 are arranged on the corresponding shim trays 70 based on initial settings and calculation results in step ST40, which will described below.

In step ST20, the shim trays 70 are inserted into the magnet gantry 100.

In step ST30, the static magnetic field magnet 10 is excited.

In step ST40, the magnetic field uniformity is measured in a state where the static magnetic field is at the rated magnetic field. For example, the magnetic field uniformity is measured based on the magnetic field strength at each position defined by three-dimensional coordinates in the bore B where the subject P is positioned, or by polar coordinates with the magnetic field center as the origin. On the basis of the measurement results of the magnetic field uniformity, the positions and quantity of the magnetic shims 74 to be disposed on each shim tray 70 in step ST10 are calculated.

In step ST50, it is determined whether the magnetic field uniformity satisfies a specified value in the imaging region S. If it is determined in step ST50 that the magnetic field uniformity satisfies the specified value (YES in step ST50), the processing is ended. If it is determined in step ST50 that the magnetic field uniformity does not satisfy the specified value (NO in step ST50), the processing proceeds to step ST60.

In step ST60, it is determined whether the magnetic force acting on each shim tray element part is smaller than a predetermined value. If the magnetic force acting on each shim tray element part is not smaller than the predetermined value (NO in step ST60), the processing proceeds to step ST70, and then to step ST80 after step ST70.

In step ST70, the static magnetic field magnet 10 is demagnetized.

In step ST80, the shim trays 70 are removed from the magnet gantry 100.

In step ST60, if the magnetic force acting on each shim tray element part is smaller than a predetermined value (YES in step ST60), the processing proceeds to step ST80. Specifically, the static magnetic field magnet 10 is not demagnetized, and each shim tray element part of the respective shim trays 70 is inserted into and removed from the magnet gantry 100 at least once in a state where the static magnetic field is at the rated magnetic field.

In a conventional shim tray that is not divided into a plurality of shim tray element parts, a large magnetic force acts on the entire shim tray during insertion and removal in a state where the static magnetic field is at the rated magnetic field, making it difficult to ensure safety during insertion and removal work. In contrast to this, in the shim trays 70 according to the exemplary embodiment, each of which is divided into a plurality of shim tray element parts, the magnetic force acting on each shim tray element part is smaller than the magnetic force acting on the entire shim tray, so that safety during insertion and removal work can be ensured even in a state where the static magnetic field is at the rated magnetic field. Thus, the shim trays 70 according to the exemplary embodiment enable a reduction in the number of times the operation in step ST70 is performed. Even in the shim trays 70 according to the exemplary embodiment, if the magnetic force acting on each shim tray element part is not smaller than a predetermined value, the operation in step ST70 may be performed.

After the operation in step ST80, the processing returns to step ST10. Specifically, after the magnetic shims 74 are arranged based on the calculation results in step ST40, the shim trays 70 are inserted into the magnet gantry 100, and the magnetic field uniformity is measured again. This series of shimming operations is repeated until the magnetic field uniformity in the imaging region S satisfies a specified value. Additionally, from the second repetition of the shimming operations onward, step ST30 is omitted if the static magnetic field magnet 10 has not been demagnetized (that is, step ST70 has not been performed).

According to the MRI apparatus 1 of the first exemplary embodiment, a shim tray includes a plurality of shim tray element parts, and the magnetic force acting on each shim tray element part is smaller than the magnetic force acting on the entire shim tray. Therefore, individually inserting and removing the shim tray element parts ensures safety during the insertion and removal operation in a state where the static magnetic field is at the rated magnetic field. In addition, reduction in the number of times the static magnetic field magnet is demagnetized and excited during the insertion and removal operation can reduce the amount of helium consumed to cool the static magnetic field magnet (e.g., about 200 liters) and the work hours (e.g., 160 hours).

If the shim tray element parts are inserted and removed from both sides of the gantry device, the insertion and removal distances for each shim tray element part is shortened. This eliminates the need for the ends of the shim tray with a large amount of magnetic shims to cross the center of the shim tray with fewer magnetic shims, allowing each shim tray element to be inserted or removed without causing variations in magnetic force during the insertion and removal work, thus avoiding potential hazards.

### Second Exemplary Embodiment

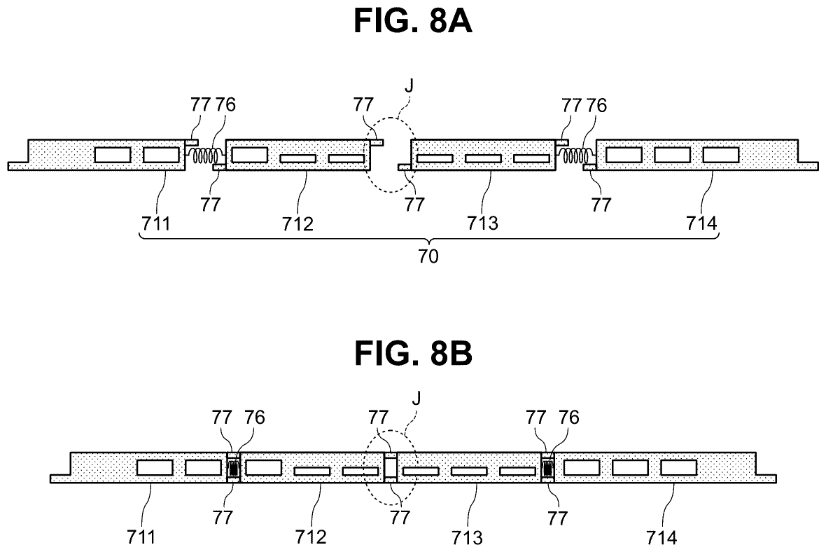

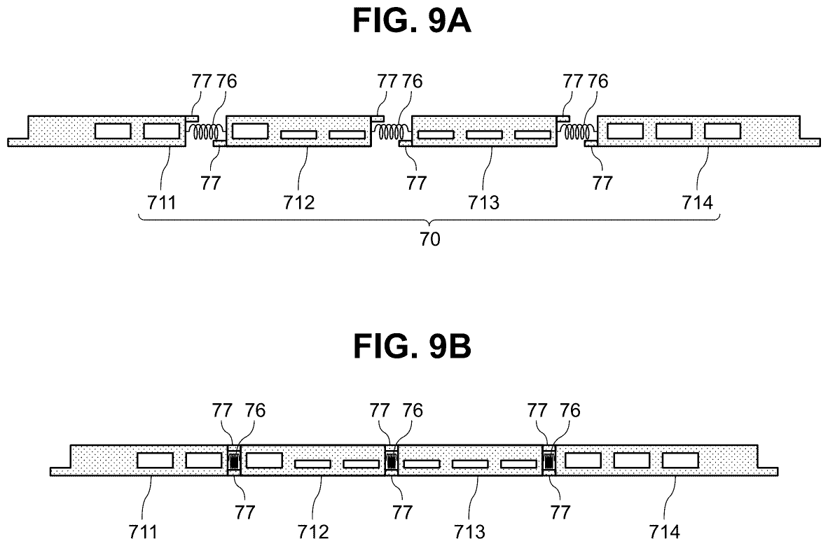

In a second exemplary embodiment, a shim tray 70 is divided into three or more shim tray element parts. In other words, the shim tray 70 may be divided into a plurality of shim tray element parts including a first shim tray element part and a second shim tray element part. FIGS. 8A, 8B, 9A, and 9B are cross-sectional diagrams illustrating a case where each shim tray element part is inserted and removed from both a first opening and a second opening (FIGS. 8A and 8B) and a case where each shim tray element part is inserted and removed through either the first opening or the second opening (FIGS. 9A and 9B). In FIGS. 8A, 8B, 9A, and 9B, the shim tray 70 includes four shim tray element parts 711 to 714.

Referring to FIG. 8A, two shim tray element parts 711 and 712 are coupled to each other by a coupling member 76, and each shim tray element part is inserted and removed through the first opening. Two shim tray element parts 713 and 714 are coupled to each other by another coupling member 76, and each shim tray element part is inserted and removed through the second opening. FIG. 8B illustrates a state in which, after the shim tray 70 in FIG. 8A is inserted into the magnet gantry 100, the two shim tray element parts 711 and 712 are fixed by a first fixing part 75a, and the two shim tray element parts 713 and 714 are fixed by a second fixing part 75b.

Each coupling member 76 is a non-magnetic body, and has a length with which, when one of the shim tray element parts (e.g., the first shim tray element part 701 in FIG. 6A) that are to be inserted and removed through the same opening and are adjacent to each other is removed from the magnet gantry 100, the one shim tray element part is kept at a predetermined distance from the magnet gantry 100 while the other shim tray element part (e.g., the second shim tray element part 702 in FIG. 6A) remains within the magnet gantry 100. If three or more shim tray element parts have been coupled and any of shim tray element parts has already been removed from the magnet gantry 100, the remaining shim tray element parts are removed in a state where the already removed shim tray element part is kept at a predetermined distance from the magnet gantry 100.

The coupling member 76 has such a length, so that it is possible to, while the removed shim tray element part is placed in a location where it is unlikely to be affected by the magnetic force of the static magnetic field, remove the other shim tray element parts in the static magnetic field, thus ensuring safety during the insertion and removal operation. Additionally, in inserting one shim tray element part into the magnet gantry 100, the other shim tray element parts are placed in a location where they are less affected by the magnetic force of the static magnetic field. This allows the work to be carried out with only the one shim tray element part being affected by the magnetic force of the magnetic field, ensuring safety during the insertion and removal work.

Each shim tray element part has convex portions 77 on the sides adjacent to other shim tray element parts with the coupling members 76 in between. As illustrated in FIG. 8B, each coupling member 76 is housed in a gap occurring between adjacent shim tray element parts coupled via the convex portions 77. Each coupling member 76 is desirably structured to be fitted in the gap, and may be structured to be rotatable at the joint with the shim tray element part and to be less prone to twisting.

Each of the shim tray element parts 712 and 713 may include or not include the convex portion 77 at a coupling part J between the shim tray element part 712 to be inserted and removed through the first opening and the shim tray element part 713 to be inserted and removed through the second opening. It is sufficient that the shim pockets 73 are arranged at predetermined intervals over the entire shim tray 70, taking into consideration the presence or absence of the convex portions 77. Additionally, each coupling member 76 may be housed in a gap inside the shim tray element parts, in which case each shim tray element part may include or not include the convex portion 77.

Referring to FIG. 9A, the four shim tray element parts 711 to 714 are coupled to each other by the coupling members 76, and each shim tray element part is inserted into and removed from the magnet gantry 100 through either the first opening or the second opening. Thus, among the plurality of shim tray element parts, adjacent shim tray element parts to be inserted and removed through the same opening are coupled to each other by the coupling member 76. FIG. 9B illustrates a state where, after the shim tray 70 in FIG. 9A is inserted into the magnet gantry 100, the four shim tray element parts 711 to 714 are fixed by the first fixing parts 75a and the second fixing parts 75b.

### Modification of Second Exemplary Embodiment

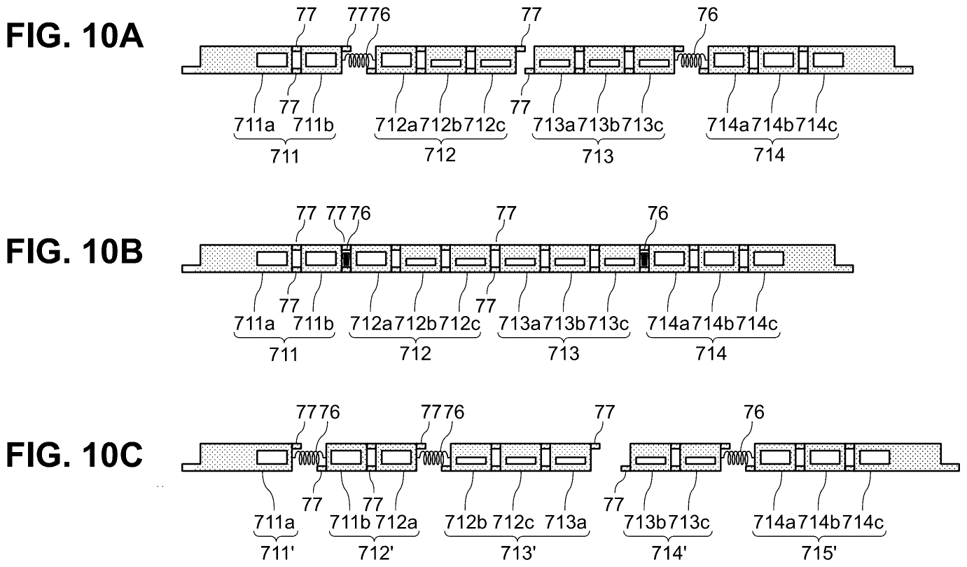

In a modification of the second exemplary embodiment, a plurality of shim tray element parts is each a coupled body of shim tray element members including one or more shim pockets 73. FIG. 10A illustrates that each of the four shim tray element parts 711 to 714 in FIG. 8A includes a plurality of shim tray element members including one shim pocket 73. Referring to FIG. 10A, the four shim tray element parts 711 to 714 respectively include two shim tray element members 711a and 711b, three shim tray element members 712a to 712c, three shim tray element members 713a to 713c, and three shim tray element members 714a to 714c, in this order.

FIG. 10B illustrates a state where, after being inserted into a magnet gantry 100, a shim tray 70 in FIG. 10A is fixed by a first fixing part 75a and a second fixing part 75b. In the modification of the second exemplary embodiment, in step ST40, the positions at which the plurality of shim tray element parts is to be divided, that is, the number of shim pockets 73 to be included in each shim tray element part, is calculated based on measurement results of magnetic field uniformity. Then, in step ST10, the plurality of shim tray element parts is divided based on the calculation result.

The shim tray 70, which has been divided into the four shim tray element parts 711 to 714 as illustrated in FIG. 10A, is divided into five shim tray element parts 711′ to 715′ as illustrated in FIG. 10C, for example. Referring to FIG. 10C, the five shim tray element parts 711′ to 715′ respectively includes one shim tray element member 711a, two shim tray element members 711b and 712a, three shim tray element members 712b, 712c, and 713a, two shim tray element members 713b and 713c, and three shim tray element members 714a, 714b, and 714c, in this order.

Each shim tray element part may include one shim tray element member, or may include a plurality of shim tray element members. Thus, the plurality of shim tray element parts may be a coupled body of shim tray element members having one or more shim pockets 73. The shim tray element members included in each shim tray element part have a joinable structure.

According to the MRI apparatus 1 of the second exemplary embodiment, each shim tray is divided into a greater number of shim tray element parts than in the first exemplary embodiment, so that the magnetic force acting on each shim tray element part is further reduced, and the shim tray can be inserted and removed more safely even in a state where the static magnetic field is at the rated magnetic field. Additionally, according to the MRI apparatus 1 of the modification of the second exemplary embodiment, the positions at which each shim tray is divided can be easily changed so that the magnetic force acting on each shim tray element part is smaller than a predetermined value, thus further improving the work efficiency.

### Third Exemplary Embodiment

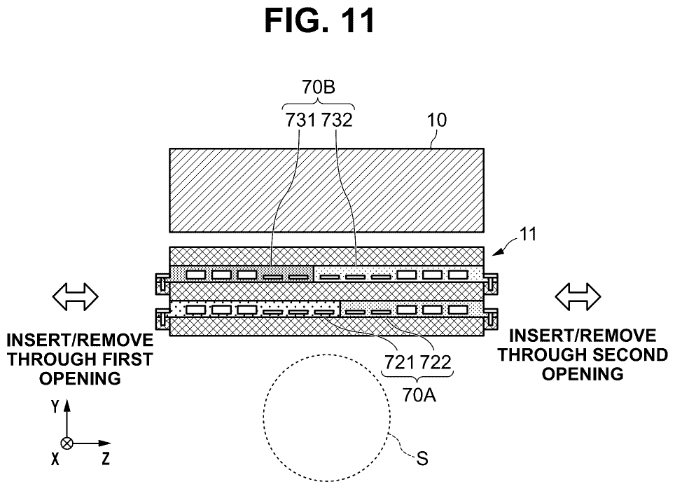

FIG. 11 is a cross-sectional view of a portion of a magnet gantry 100 of an MRI apparatus 1 according to a third exemplary embodiment. In the first and second exemplary embodiments, the plurality of shim trays 70 is arranged in a circle from the center of the bore B along the axial direction of the bore B, whereas in the third exemplary embodiment, a plurality of shim trays 70A and 70B is arranged in a plurality of (two in FIG. 11) concentric circles at different distances from the center of a bore B along the axial direction of the bore B. The shim trays 70A and 70B are examples of the shim tray 70.

Referring to FIG. 11, the shim tray 70A includes two shim tray element parts 721 and 722, and the shim tray 70B includes two shim tray element parts 731 and 732. The plurality of shim trays 70A and 70B may have the same total magnetic force, or may have different total magnetic forces.

The shim trays 70A and 70B are each divided into a plurality of shim tray element parts based on positions along the axial direction of the bore B and the magnetic forces acting on the shim trays 70A and 70B in accordance with the positions. The shim trays 70A and 70B are each divided into a plurality of shim tray element parts so that the magnetic force acting on each shim tray element part is smaller than a predetermined value.

According to the MRI apparatus 1 of the third exemplary embodiment, the shim trays are each divided into a plurality of shim tray element parts, and are located at different distances from the center of the bore B. Thus, the magnetic force acting on each shim tray element part is further reduced, and the shim trays can be inserted and removed more safely even in a case where the static magnetic field is at the rated magnetic field.

According to at least one of the MRI apparatuses and the shim tray of the exemplary embodiments described above, the number of times the static magnetic field magnet is demagnetized in the shimming of the MRI apparatus can be reduced.

While certain embodiments have been described, these embodiments have been presented by way of example only, and are not intended to limit the scope of the invention. Indeed, the novel embodiments described herein may be embodied in a variety of other forms; furthermore, various omissions, substitutions and changes in the form of the embodiments described herein may be made without departing from the spirit of the invention. The accompanying claims and their equivalents are intended to cover such forms or modifications as would fall within the scope and spirit of the invention.

What is claimed is:

1. A magnetic resonance imaging apparatus, comprising:
a magnet gantry including a magnet configured to generate a static magnetic field in a bore in which a subject is positioned;
a shim tray including a first shim tray element part and a second shim tray element part, the first shim tray element part including a first shim pocket in which a magnetic shim which is configured to adjust the static magnetic field is stored, the second shim tray element part including a second shim pocket in which the magnetic shim is stored,
wherein each of the first shim tray element part and the second shim tray element part is inserted into and removed from the magnet gantry along an axial direction of the bore through at least one of openings provided on one end side of the magnet gantry and the other end side of the magnet gantry in the axial direction.

2. The magnetic resonance imaging apparatus according to claim 1,
wherein the magnet gantry further includes a gradient magnetic field coil configured to generate a gradient magnetic field, and
wherein the shim tray is inserted into and removed from a shim slot in the gradient magnetic field coil along the axial direction.

3. The magnetic resonance imaging apparatus according to claim 1,
wherein the first shim tray element part is inserted into and removed from the magnet gantry along the axial direction through the opening provided on the one end side of the magnet gantry in the axial direction, and
the second shim tray element part is inserted into and removed from the magnet gantry along the axial direction through the opening provided on the other end side of the magnet gantry in the axial direction.

4. The magnetic resonance imaging apparatus according to claim 1, wherein the shim tray is divided into a plurality of shim tray element parts including the first shim tray element part and the second shim tray element part such that magnetic force acting on each shim tray element part is smaller than a predetermined value.

5. The magnetic resonance imaging apparatus according to claim 1, wherein the shim tray is divided into a plurality of shim tray element parts including the first shim tray element part and the second shim tray element part based on positions along the axial direction and magnetic force acting on the shim tray in accordance with the positions.

6. The magnetic resonance imaging apparatus according to claim 1, wherein the first shim tray element part and the second shim tray element part are inserted into and removed from the magnet gantry at least once in a state where the static magnetic field is at a rated magnetic field.

7. The magnetic resonance imaging apparatus according to claim 1, wherein the first shim tray element part and the second shim tray element part that are inserted and removed through the same opening and are adjacent to each other, are coupled to each other by a coupling member.

8. The magnetic resonance imaging apparatus according to claim 7, wherein the coupling member is a non-magnetic body and has a length with which, in a case where the first shim tray element part is removed from the magnetic gantry, the first shim tray element part is kept at a predetermined distance from the magnetic gantry while the second shim tray element part remains within the magnetic gantry.

9. The magnetic resonance imaging apparatus according to claim 1,
wherein the first shim tray element part is fixed to a first fixing part on the one end side of the magnet gantry in the axial direction, and
wherein the second shim tray element part is fixed to a second fixing part provided on the other end side of the magnet gantry in the axial direction.

10. A shim tray to be inserted into and removed from a magnet gantry along an axial direction of a bore in which a subject is positioned, the magnetic gantry including a magnet configured to generate a static magnetic field in the bore and being included in a magnetic resonance imaging apparatus, the shim tray comprising:
a first shim tray element part including a first shim pocket in which a magnetic shim which is configured to adjust the static magnetic field is stored a second shim tray element part including a second shim pocket in which the magnetic shim is stored,
wherein each of the first shim tray element part and the second shim tray element part is inserted into and removed from the magnet gantry along an axial direction of the bore through at least one of openings provided on one end side of the magnet gantry and the other end side of the magnet gantry in the axial direction.

11. The shim tray according to claim 10,
wherein the first shim tray element part is inserted into and removed from the magnet gantry along the axial direction through the opening provided on the one end side of the magnet gantry in the axial direction, and
the second shim tray element part is inserted into and removed from the magnet gantry along the axial direction through the opening provided on the other end side of the magnet gantry in the axial direction.

12. The shim tray according to claim 1,
wherein the first shim tray element part is fixed to a first fixing part on the one end side of the magnet gantry in the axial direction, and
wherein the second shim tray element part is fixed to a second fixing part provided on the other end side of the magnet gantry in the axial direction.
